(19) United States
(12) Patent Application Publication
(10) Pub. No.: US 2025/0236514 A1
(43) Pub. Date: Jul. 24, 2025

(54) CHEMICAL STOP STRUCTURES FOR MEMS DEVICES

(71) Applicant: Taiwan Semiconductor Manufacturing Company LTD, Hsinchu (TW)

(72) Inventors: Ko-Li Wu, Pingtung (TW); Fu Wei Liu, Tainan (TW); Wan-Yu Chiang, Chiayi (TW); Jhao-Yi Wang, Tainan (TW); Pei-Wei Lee, Pingtung (TW)

(21) Appl. No.: 18/421,236

(22) Filed: Jan. 24, 2024

(51) Int. Cl. B81C 1/00; B81B 7/00

(52) U.S. Cl. CPC B81C 1/00523; B81B 7/0025

(57) ABSTRACT

In a micro-electromechanical system (MEMS) structure, at least one chemical stop structure is formed to reduce inadvertent etching of adhesion layers. A first adhesion layer and a second adhesion layer are separated by a primary dielectric layer. The primary dielectric layer includes a recess that forms a stair. The second adhesion layer includes an annular opening, and a protective material covers the sides of the second adhesion layer in the annular opening. A base plate layer covers the second adhesion layer and fills the recess and the annular opening. An annular via passes through the base plate layer and the protective material down to the primary dielectric layer. The protective material and the base plate layer each act as chemical stop structures that separate the first adhesion layer from the second adhesion layer.

### BACKGROUND

Micro-electromechanical systems (MEMS) is a technology that employs miniature mechanical and electro-mechanical elements (e.g., devices or structures) on a wafer substrate. Utilizing micro-fabrication techniques, MEMS devices may range from relatively simple structures with no moving elements, to complex electro-mechanical systems utilizing a variety of moving elements under the control of an integrated microelectronic controller. Devices or structures that can be used in MEMS include microsensors, micro-actuators, microelectronics, and microstructures. MEMS devices may be used in a wide range of applications, including, for example and without limitation, motion sensors, pressure sensors, inertial sensors, micro-fluidic devices (e.g., valves, pumps, nozzle controls), optical devices, imaging devices (e.g., micromachined ultrasonic transducers (“MUT”s)), capacitive MUT (“CMUT”) ultrasound transducers, and the like.

MEMS structures can be made using photolithographic patterning processes that use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are various views of a first example embodiment of a MEMS structure, in accordance with some embodiments of the present disclosure. Here, a chemical stop structure is present in the second adhesion layer and the base plate also forms a chemical stop structure. FIG. 1A is a Y-axis cross-sectional view through line A-A of FIG. 1B. FIG. 1B is a plan view from the top. FIG. 1C is a Y-axis cross-sectional view through line C-C of FIG. 1B, and shows additional information.

FIG. 1D is a Y-axis cross-sectional view showing a second example embodiment of a MEMS structure, in accordance with some embodiments of the present disclosure, through line A-A of FIG. 1B. Here, a chemical stop structure is present in the second adhesion layer.

FIG. 1E is a Y-axis cross-sectional view showing a third example embodiment of a MEMS structure, in accordance with some embodiments of the present disclosure, through line A-A of FIG. 1B. Here, the base plate forms a chemical stop structure.

FIG. 2 is a flow chart illustrating a first method for forming a base plate for a MEMS device that includes one or more chemical stop structures, in accordance with some embodiments. Various steps of this method are shown in FIGS. 3-9.

FIG. 3 is a Y-axis cross-sectional view through line A-A of FIG. 1B, showing a substrate with an intermetal dielectric layer surrounding an intermetal layer and a top metal layer.

FIG. 4 is a Y-axis cross-sectional view through line A-A of FIG. 1B, showing the substrate after a first adhesion layer, a primary dielectric layer, and a second adhesion layer are formed upon the substrate.

FIG. 5A is a Y-axis cross-sectional view through line A-A of FIG. 1B, showing the substrate after the second adhesion layer has been patterned to expose a recess opening and an annular opening.

FIG. 5B is a plan view of the substrate of FIG. 5A.

FIG. 6 is a Y-axis cross-sectional view through line A-A of FIG. 1B, showing the substrate after a partial etch of the primary dielectric layer has formed a recess above the top metal layer.

FIG. 7A is a Y-axis cross-sectional view through line A-A of FIG. 1B, showing the substrate after etching the recess down to the first adhesion layer to form a stair.

FIG. 7B is a plan view of the substrate of FIG. 7A.

FIG. 8A is a plan view of the substrate after etching through the recess down to the top metal layer, and after protective material is deposited in the annular opening of the second adhesion layer.

FIG. 8B is a first Y-axis cross-sectional view of the substrate of FIG. 8A through line B-B, which corresponds to line A-A of FIG. 1B.

FIG. 8C is a second Y-axis cross-sectional view of the substrate of FIG. 8A through line C-C.

FIG. 9 is a Y-axis cross-sectional view through line B-B of FIG. 8A, showing the substrate after a base plate material has been deposited over the second adhesion layer and into the recess.

FIG. 10 is a flow chart illustrating a second method for forming a base plate for a MEMS device that includes one or more chemical stop structures, in accordance with some embodiments. Various steps of this method are shown in FIGS. 11-14.

FIG. 11 is a Y-axis cross-sectional view through line A-A of FIG. 1B, showing the substrate after a partial etch of the primary dielectric layer has formed a recess above the top metal layer.

FIG. 12 is a Y-axis cross-sectional view through line A-A of FIG. 1B, showing the substrate after the second adhesion layer has been deposited and patterned to expose a recess opening and an annular opening, and etching has been performed through the recess opening down to the first adhesion layer. The second adhesion layer is also present on the stair.

FIG. 13 is a Y-axis cross-sectional view through line A-A of FIG. 1B, showing the substrate after protective material is deposited in the annular opening of the second adhesion layer, the base plate material has been deposited, and an annular via has been formed through the protective material to the primary dielectric layer.

FIG. 14 is a flow chart illustrating a third method for forming a base plate for a MEMS device that include a chemical stop structure, in accordance with some embodiments. Various steps of this method are shown in FIGS. 15-16.

FIG. 15 is a Y-axis cross-sectional view through line A-A of FIG. 1B, showing the substrate after etching a recess in the primary dielectric layer down to the first adhesion layer, and subsequent deposition of the second adhesion layer.

FIG. 16 is a Y-axis cross-sectional view through line A-A of FIG. 1B, showing the substrate after forming an annular opening in the second adhesion layer, depositing protective material in the annular opening, and depositing a base plate material.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The term “up to X” is used in this disclosure to indicate an amount of a given material. This term should be construed to require the given material to be present in an amount greater than zero, or in other words to exclude the value zero.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The term “annular” is used herein to refer to a structure that forms a ring. The ring may be of any shape, such as circular, square, triangular, etc.

Various embodiments of the present disclosure relate to micro-electromechanical system (MEMS) structures that can be used in various devices. The adhesion layer of some MEMS structures can be exposed to etching chemicals which are intended to etch other layers but will also attack the material of the adhesion layer. This can cause peeling of the layers which were originally bound together by the adhesion layer, such as a base plate for a pillar with a high aspect ratio. In addition, other layers can peel if there is a path from the exposed adhesion layer down to other adhesion layers within the MEMS structure. In various embodiments of the present disclosure, chemical stop structures are disclosed for protecting adhesion layers present within the MEMS structure.

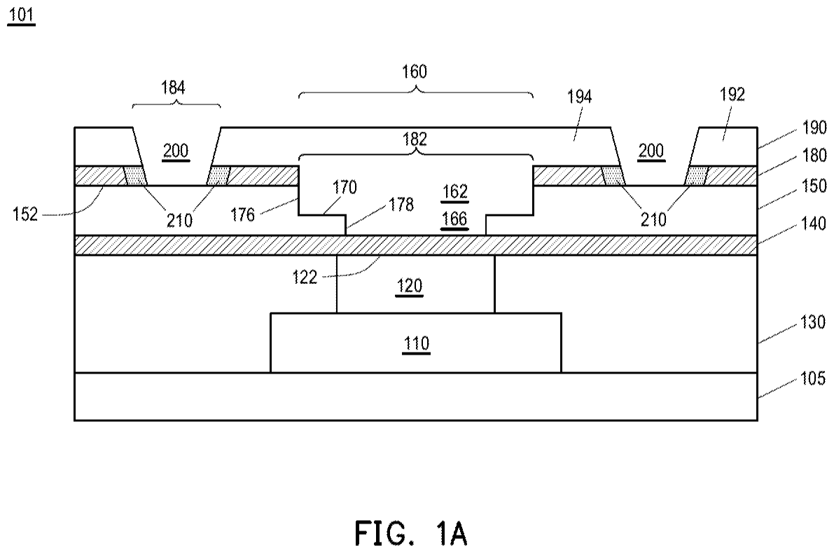

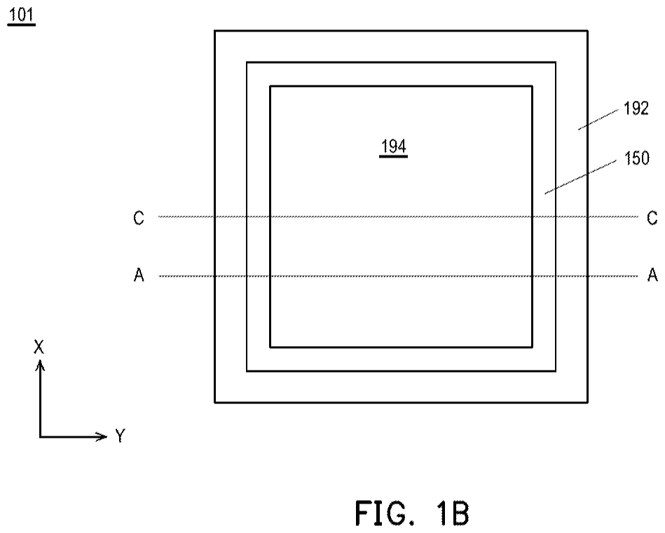

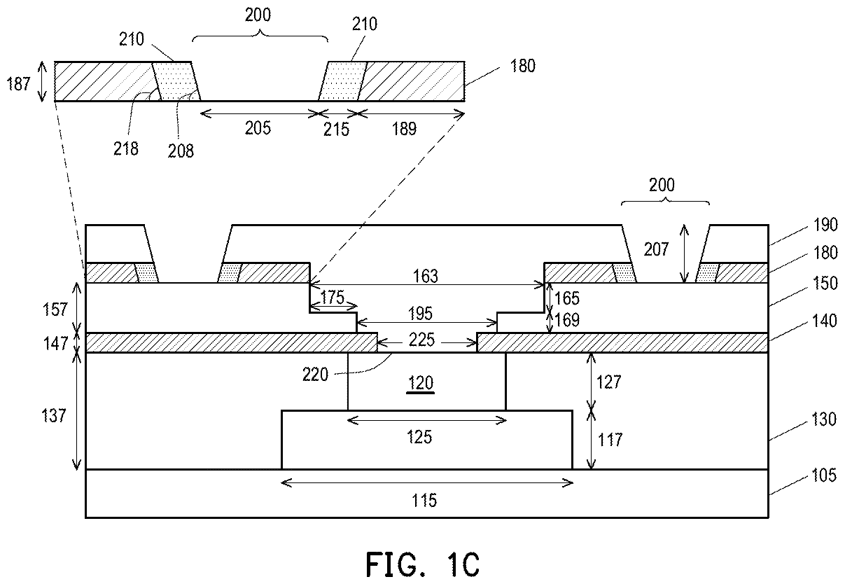

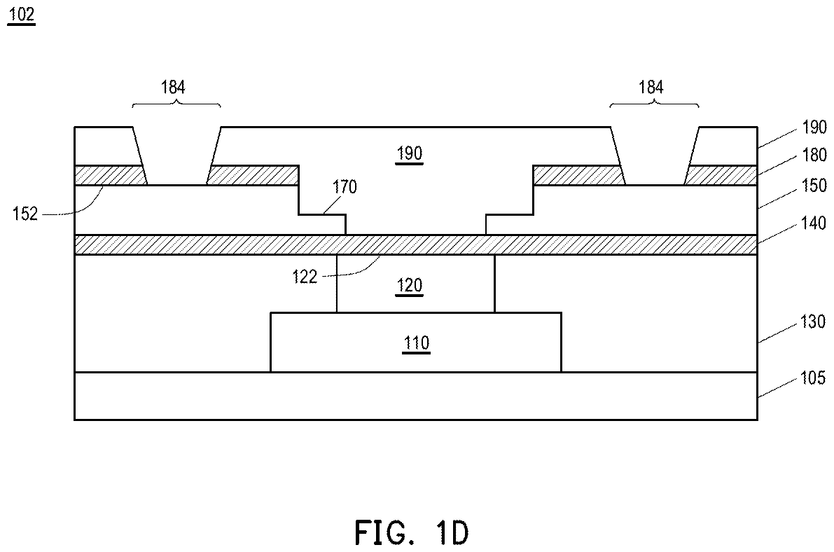

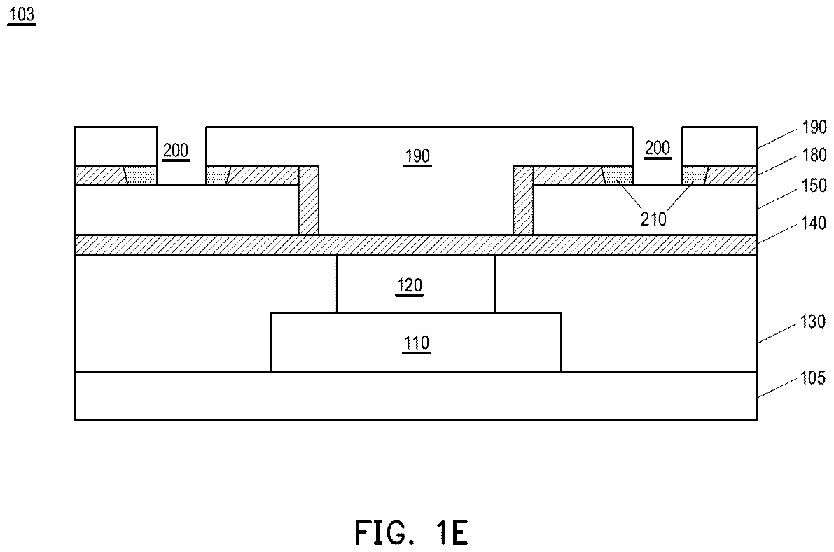

FIGS. 1A-1C are various views of a first example embodiment of a MEMS structure 101, in accordance with some embodiments of the present disclosure. FIG. 1A is a Y-axis cross-sectional view through line A-A of FIG. 1B. FIG. 1B is a plan view from the top. FIG. 1C is a Y-axis cross-sectional view through line C-C of FIG. 1B.

Referring first to FIG. 1A, the MEMS structure is formed on a substrate 105. An intermetal layer 110 is present upon the substrate. A top metal layer 120 is present upon the intermetal layer 110, or put another way the intermetal layer is located below the top metal layer. An intermetal dielectric (IMD) layer 130 surrounds the intermetal layer 110 and the top metal layer 120. Put another way, the intermetal layer 110 and the top metal layer 120 are present within the IMD layer 130. The upper surface 122 of the top metal layer 120 is exposed, or in other words is not covered by the IMD layer 130.

A first adhesion layer 140 is formed over the IMD layer 130. A primary dielectric layer 150 is formed over the first adhesion layer 140. The upper surface 152 of the primary dielectric layer 150 includes a recess 160 that is shaped to include a stair 170, or in other words a horizontal surface within the primary dielectric layer that is below the upper surface 152 and above the first adhesion layer 140. An upper rise 176 at one end of the stair extends to the upper surface 152. A lower rise 178 at an opposite end of the stair extends to the first adhesion layer 140. The recess 160 itself may be considered as being formed from an upper recess portion 162 and a lower recess portion 166. The primary dielectric layer 150 also serves as a protective layer for the first adhesion layer 140 and the IMD layer 130.

Continuing in FIG. 1A, a second adhesion layer 180 is present upon the primary dielectric layer 150. In this embodiment, the second adhesion layer 180 rests on the upper surface 152 of the primary dielectric layer, and is not present in recess 160. Put another way, the second adhesion layer includes a recess opening 182 which is present over the top metal layer 120. A base plate layer 190 covers the second adhesion layer 180 and also fills the recess 160.

An annular via 200 is present around the recess 160. The annular via extends through the base plate layer 190 and the second adhesion layer 180 down to the primary dielectric layer 150. No material is present in the annular via 200, or in other words the annular via is empty. The annular via is present within an annular opening 184 in the second adhesion layer 180, and a protective material 210 covers the sides of the second adhesion layer in the annular opening. The annular via also separates the base plate layer 190 into a perimeter portion 192 and a center portion 194, which are located on opposite sides of the annular via. The annular via may also be described as passing through the protective material 210. The protective material 210 separates the annular via 200 from the second adhesion layer 180. It is noted that although referred to as a layer, the center portion 194 of the base plate layer may extend upwards, for example to form a pillar. The center portion 194 of the base plate layer is electrically isolated by the annular via 200.

As can be seen here, two different chemical stop structures are present. The first chemical stop structure is the protective material 210, which prevents etching chemicals from contacting the second adhesion layer 180. The second chemical stop structure is the base plate layer 190, which separates the second adhesion layer 180 from the first adhesion layer 140 and blocks any chemical etching path to the first adhesion layer.

Referring now to the plan view of FIG. 1B, the perimeter portion 192 and the center portion 194 of the base plate layer are indicated. The primary dielectric layer 150 is visible through the annular via. It should also be noted that line A-A (where the cross-sectional view of FIG. 1A is taken) is offset from the centerline C-C.

The first adhesion layer 140 itself may be made of a conductive metal, which permits current to flow from the top metal layer into the base plate layer. Alternatively, in some embodiments as illustrated in FIG. 1C, there may also be a through-via 220 that extends from the recess through the first adhesion layer 140, so the base plate layer 190 can contact the top metal layer 120. This optional through-via, when present, may be filled with the base plate material used to form the base plate layer. Various dimensions of the separate components of the MEMS structure are indicated in this figure.

The intermetal layer 110 has a width 115 and a depth 117. In particular embodiments, the width 115 is from about 0.5 micrometers (μm) to about 10 μm. In particular embodiments, the depth 117 is from about 0.5 μm to about 5 μm. Combinations of the width and depth are also contemplated. Other ranges and values for each of these properties are also within the scope of this disclosure.

The top metal layer 120 has a width 125 and a depth 127. The width 125 of the top metal layer is generally less than the width 115 of the intermetal layer 110. In particular embodiments, the width 125 is from about 0.5 μm to about 10 μm. In particular embodiments, the depth 127 is from about 0.5 μm to about 5 μm. Combinations of the width and depth are also contemplated. Other ranges and values for each of these properties are also within the scope of this disclosure.

The IMD layer 130 has a depth 137. In particular embodiments, the depth 137 is from about 0.5 μm to about 15 μm. Other ranges and values are also within the scope of this disclosure.

The first adhesion layer 140 has a depth 147. In particular embodiments, the depth 147 is up to about 10 μm. In some embodiments, the depth is at least 0.1 μm. Other ranges and values are also within the scope of this disclosure.

The primary dielectric layer 150 has a depth 157. In particular embodiments, the depth 157 is from about 0.2 μm to about 200 μm. Other ranges and values are also within the scope of this disclosure.

The bottom of the base plate has a width 195. In particular embodiments, the width 195 is from about 0.5 μm to about 100 μm. Other ranges and values are also within the scope of this disclosure. The width of the lower recess portion 166 is also equal to width 195. The width 125 of the top metal layer is less than or equal to the width 195 of the bottom of the base plate.

The lower recess portion 166 and the lower rise 178 each have the same depth 169. In particular embodiments, the depth 169 is from about 0.1 μm to about 100 μm. Other ranges and values are also within the scope of this disclosure.

When present, the through-via 220 has a width 225. The width 225 of the through-via is less than or equal to the width 195 of the bottom of the base plate. In particular embodiments when present, the width 225 is up to about 100 μm. Other ranges and values are also within the scope of this disclosure.

The upper recess portion 162 has a width 163. In particular embodiments, the width 163 is from about 0.5 μm to about 300 μm. Other ranges and values are also within the scope of this disclosure. The width 163 of the upper recess portion 162 is greater than the width 195 of the bottom of the base plate. The width 163 of the upper recess portion 162 is also greater than the width 225 of the through-via.

The upper recess portion 162 and the upper rise 176 each have the same depth 165. In particular embodiments, the depth 165 is from about 0.1 μm to about 100 μm. Other ranges and values are also within the scope of this disclosure.

The stair 170 has a width 175. In particular embodiments, the width 175 is up to about 100 μm. In some embodiments, the width is at least 0.1 μm. Combinations are contemplated. Other ranges and values are also within the scope of this disclosure.

The second adhesion layer 180 has a depth 187. In particular embodiments, the depth 187 is from about 0.1 μm to about 10 μm. Other ranges and values are also within the scope of this disclosure. The depth of the protective material is the same as the depth of the second adhesion layer.

The protective material 210 on each side of the annular via 200 has a width 215. In particular embodiments, the width 215 is up to about 10 μm. In some embodiments, the width is at least 0.1 μm. Other ranges and values are also within the scope of this disclosure.

The portion 188 of the second adhesion layer 180 between the protective material 210 and the recess 160 has a width 189. In particular embodiments, the width 189 is up to about 100 μm. In some embodiments, the width is at least 0.1 μm. Other ranges and values are also within the scope of this disclosure.

The annular via 200 has a width 205 and a depth 207. The width is measured at the bottom of the annular via, next to the primary dielectric layer. In particular embodiments, the width 205 is from about 0.1 μm to about 100 μm. In particular embodiments, the depth 207 is from about 0.2 μm to about 200 μm. Combinations of the width and depth are also contemplated. Other ranges and values for each of these properties are also within the scope of this disclosure.

The annular via has a taper angle 208. In particular embodiments, the taper angle 208 is from about 30° to about 135°. Other ranges and values are also within the scope of this disclosure. The protective material also has a taper angle 218. In particular embodiments, the taper angle 218 is from about 30° to about 135°. Other ranges and values are also within the scope of this disclosure. In more particular embodiments, the annular via taper angle 208 is greater than the protective material taper angle 218. In this regard, a taper angle greater than 90° would indicate the width at the bottom of the annular via/protective material is greater at the width at the top of the annular via/protective material. Such a shape can be obtained, for example, by performing both dry etching and wet etching when forming the annular via/the annular opening.

FIG. 1D is a Y-axis cross-sectional view showing a second example embodiment of a MEMS structure 102, in accordance with some embodiments of the present disclosure. Here, no protective material is present in the annular opening 184 of the second adhesion layer. However, a stair 170 is present in the primary dielectric layer 150, and the base plate forms a chemical stop structure. The first adhesion layer 140 and the second adhesion layer 180 do not contact each other.

FIG. 1E is a Y-axis cross-sectional view showing a third example embodiment of a MEMS structure 103, in accordance with some embodiments of the present disclosure. In this embodiment, the protective material 210 is the chemical stop structure that prevents etching chemicals from contacting the second adhesion layer 180. Thus, as illustrated here, there is no stair present in the primary dielectric layer 150, and the second adhesion layer 180 can contact the first adhesion layer 140. In addition, the annular via 200 is illustrated as having a rectangular shape, rather than a trapezoidal shape that narrows going down towards the primary dielectric layer.

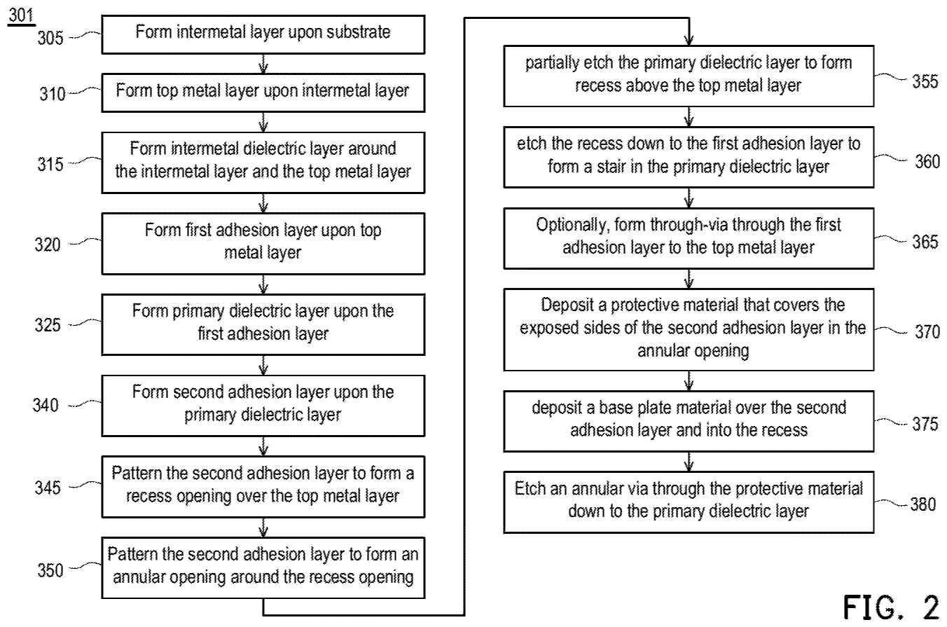

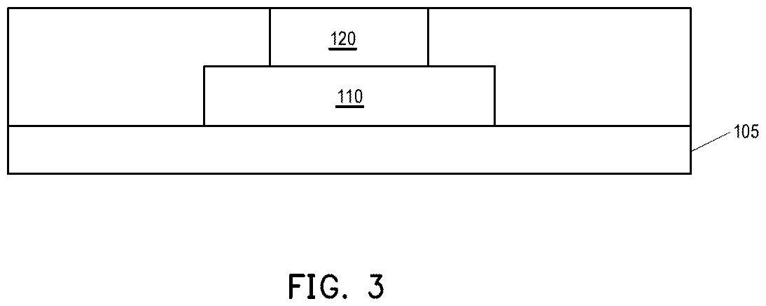

FIG. 2 is a flow chart illustrating a first method 300 for forming a base plate for a MEMS device, and for forming one or more chemical stop structures to reduce etching of an adhesion layer, in accordance with some embodiments. Some steps of the method are also illustrated in FIGS. 3-9. These figures provide different views for better understanding. While the method steps are discussed below in terms of forming a single base plate, such discussion should also be broadly construed as applying to the concurrent formation of multiple base plates.

Referring first to FIG. 3, in step 305 of FIG. 2, an intermetal layer 110 is formed upon a substrate 105. Then, in step 310 of FIG. 2, a top metal layer 120 is formed upon the intermetal layer 110. Then, in step 315 of FIG. 2, an IMD layer 130 is formed around the intermetal layer 110 and the top metal layer 120. The resulting structure is illustrated in FIG. 3. The upper surface 122 of the top metal layer 120 is exposed.

The substrate 105 may be, for example, a wafer made of a semiconducting material. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the substrate is silicon.

The substrate 105 may alternatively be a semiconductor die containing one or more integrated circuits. Integrated circuits are built up from different patterns of electrically conductive materials and electrically insulating materials to make useful components. Suitable examples of integrated circuit components may include, for example and without limitation, active components (e.g., transistors), passive components (e.g., capacitors, inductors, resistors, and the like), or combinations thereof. For example, the substrate could be a CMOS device.

The intermetal layer 110 and the top metal layer 120 may generally be formed from any conductive metal. Examples of such metals may include copper, aluminum, nickel, chromium, gold, germanium, silver, titanium, tungsten, platinum, tantalum, ruthenium, cobalt, rhenium, palladium, or zirconium; composites like TIN, WN, or TaN; or alloys thereof. The metal may be deposited, for example, via evaporation or sputtering, plating, chemical vapor deposition (CVD), physical vapor deposition (PVD), atomic layer deposition (ALD), or other suitable methods. In particular embodiments, the intermetal layer 110 and the top metal layer 120 are each formed from copper.

The IMD layer may be formed by any suitable means, including CVD, PVD, thermal oxidation, or other suitable methods. Chemical-mechanical planarization (CMP) or selective etching may be used to remove excess deposited material. In some particular embodiments, the IMD layer is formed from silicon nitride (SiN).

It is noted that the intermetal layer 110, the top metal layer 120, and the IMD layer 130 may be formed in multiple ways. For example, the intermetal layer may be deposited and patterned, then the top metal layer is deposited and patterned, then the IMD layer is deposited. If the intermetal layer 110 and the top metal layer 120 are made of the same metal, then a single metal layer would be deposited and patterned, and the IMD layer would then be deposited. As another example, a first dielectric sublayer could be formed with a first recess, then the intermetal layer could be deposited into the recess, then a second dielectric sublayer could be formed with a second recess and the top metal layer would be deposited into the second recess, with the two dielectric sublayers together forming the IMD layer.

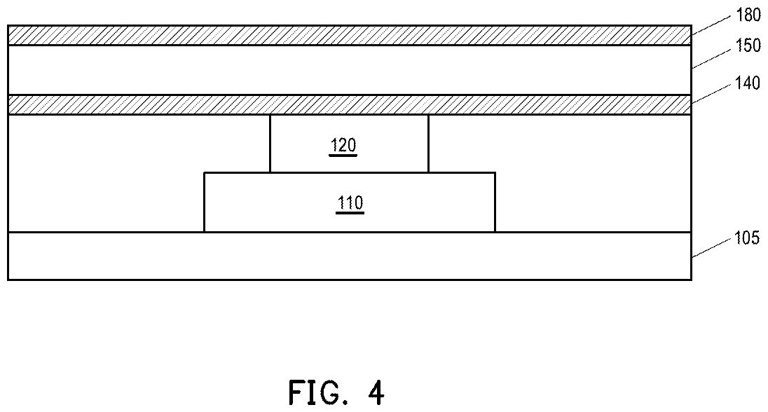

Referring next to FIG. 4, in step 320 of FIG. 2, a first adhesion layer 140 is formed upon the top metal layer 120 and the IMD layer 130. Then, in step 325 of FIG. 2, a primary dielectric layer 150 is formed upon the first adhesion layer 140. In step 340 of FIG. 2, a second adhesion layer 180 is formed upon the primary dielectric layer 150. The resulting structure is illustrated in FIG. 4. In some particular embodiments, the primary dielectric layer is formed from silicon nitride (SiN).

The first adhesion layer 140 and the second adhesion layer 180 generally are any material that causes adhesion between the base plate layer 190 and the primary dielectric layer 150. In some particular embodiments, the two adhesion layers are made of titanium. The adhesion layers may be formed, for example, via evaporation or sputtering, CVD PVD, or ALD.

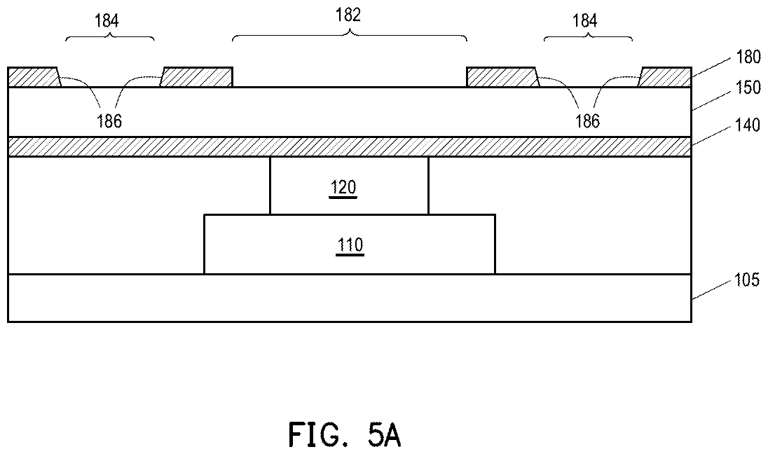

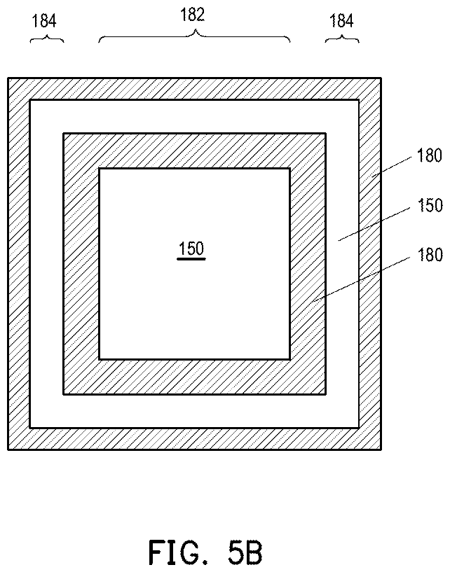

Next, as illustrated in FIG. 5A and FIG. 5B, the second adhesion layer 180 is patterned to form a recess opening 182 as indicated in step 345 of FIG. 2. The second adhesion layer 180 is also patterned to form an annular opening 184 as indicated in step 350 of FIG. 2. It is noted that the formation of these two openings is identified as two separate steps in FIG. 2, but when they are both formed, they are formed together in the same etching step. One or both steps are required. The exposed sides of the second adhesion layer are indicated with reference numeral 186. As seen in the plan view of FIG. 5B, the annular opening 184 surrounds the recess opening 182. The primary dielectric layer 150 is exposed through both openings 182, 184. The recess opening is formed above or over the top metal layer 120.

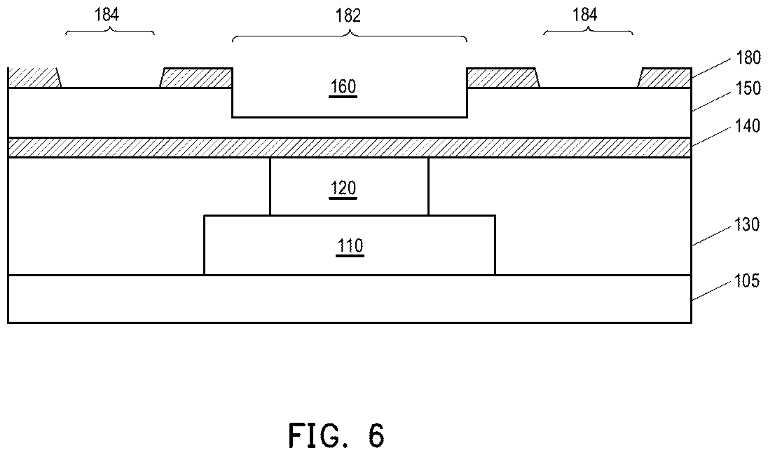

Then, in step 355 of FIG. 2 and as illustrated in FIG. 6, the primary dielectric layer 150 is partially etched to form a recess 160 above the top metal layer 120. In other words, the recess does not pass entirely through the primary dielectric layer, and the first adhesion layer is not exposed through the recess. This partial etching is performed through the recess opening in the second adhesion layer 180. The etching time is controlled to control the depth of the recess 160. This is done by forming a mask (e.g. photoresist layer), and then performing the partial etch through the mask.

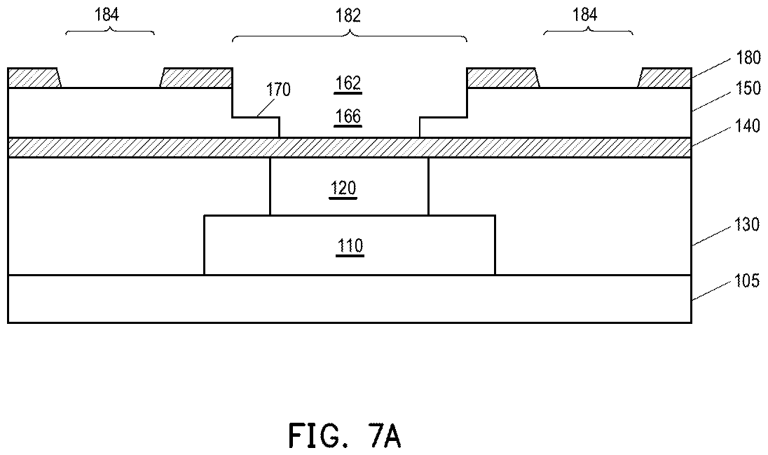

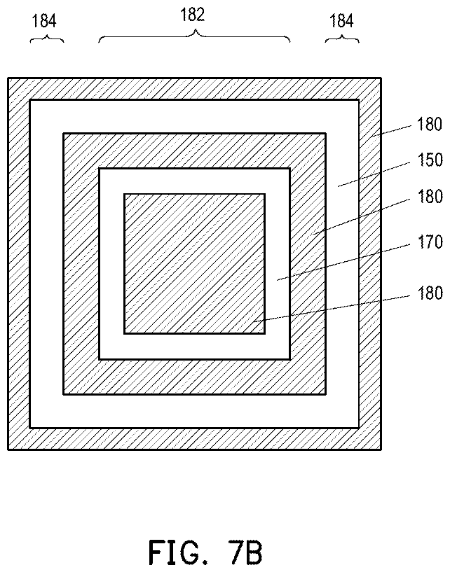

Then, in step 360 of FIG. 2 and as illustrated in FIG. 7A and FIG. 7B, the recess 160 in the primary dielectric layer 150 is patterned to form a stair down to the first adhesion layer 140. The patterning process includes forming a mask that exposes part of the recess, then etching through the mask within the recess down to the first adhesion layer. The stair 170 is formed by this patterning/etching step. The recess is now formed from an upper recess portion 162 and a lower recess portion 166. Referring now to FIG. 7B, the stair 170 and the first adhesion layer 140 are now exposed in addition to the second adhesion layer 180 and the primary dielectric layer 150 in the annular opening 184.

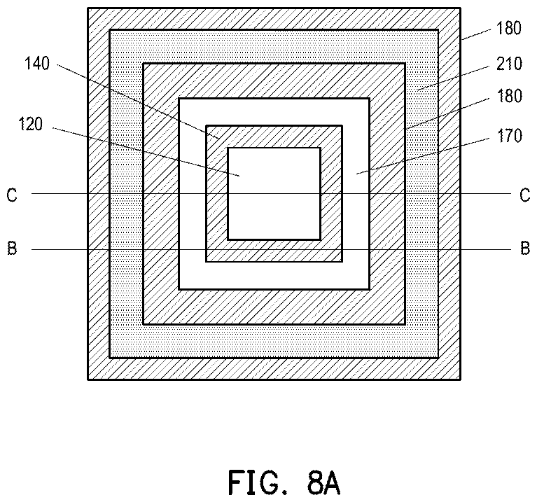

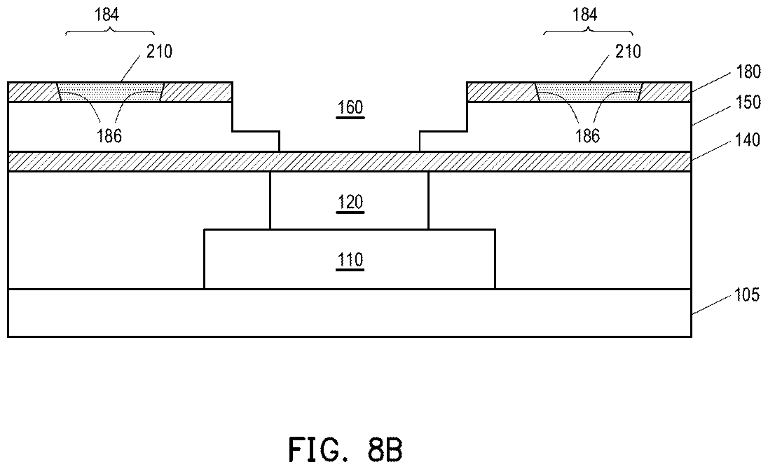

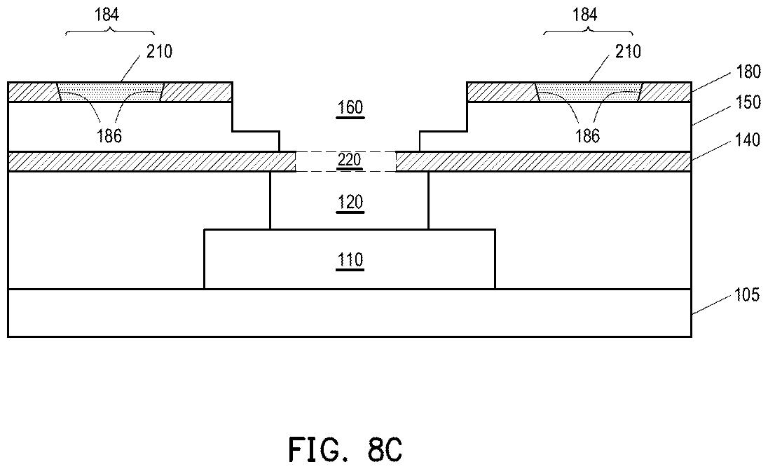

If desired, in optional step 365 of FIG. 2 and as illustrated in FIGS. 8A-8C, the first adhesion layer 140 in the recess 160 is etched to form a through-via 220 from the recess 160 to the top metal layer 120. Continuing, in step 370 of FIG. 2, a protective material 210 is deposited in the annular opening 184. The protective material forms a layer that covers the exposed sides 186 of the second adhesion layer 180 in the annular opening 184. FIG. 8B is a Y-axis cross-sectional view taken along line B-B of FIG. 8A, which does not pass through the through-via. FIG. 8C is a Y-axis cross-sectional view taken along line C-C of FIG. 8A, which does pass through the through-via 220. The protective material 210 is a metal that is different from the metal used to form the second adhesion layer 180, and thus has a different etch selectivity from the second adhesion layer. As a result, the protective material will not be etched by materials that would etch the second adhesion layer. In particular embodiments, the protective material is copper or nickel, or is made of the same material as the base plate layer. Again, the through-via is optional and is not required.

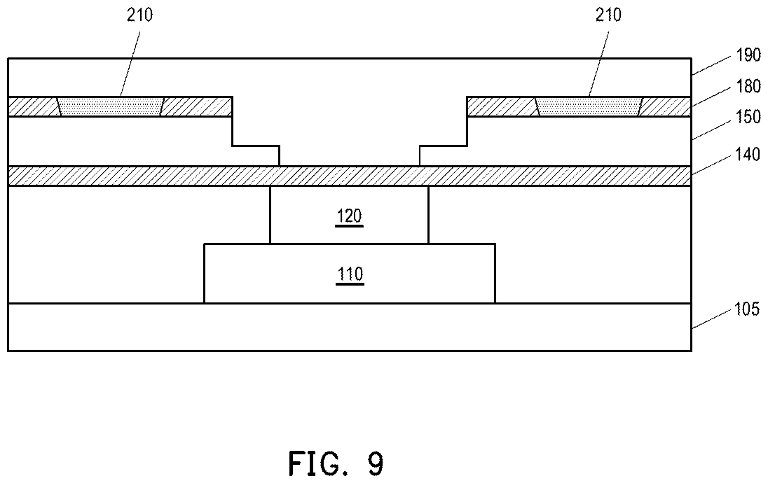

Then, in step 375 of FIG. 2 and as illustrated in FIG. 9, a base plate material is deposited over the second adhesion layer and into the recess to form the base plate layer 190. The base plate material also fills the through-via (if present). It should be emphasized again that the base plate layer does not need to have a uniform thickness, and for example may have the shape of a pillar above the recess. The base plate material may be any conductive metal as previously described. In some particular embodiments where the protective material and the base plate material are the same material, they may be deposited in the same deposition step.

Then, in step 380 of FIG. 2 and referring back to FIG. 1A, an annular via 200 is etched through the protective material layer 210 down to the primary dielectric layer 150. The protective material thus separates the annular via from the second adhesion layer 180. The final structure is thus shown in FIG. 1A.

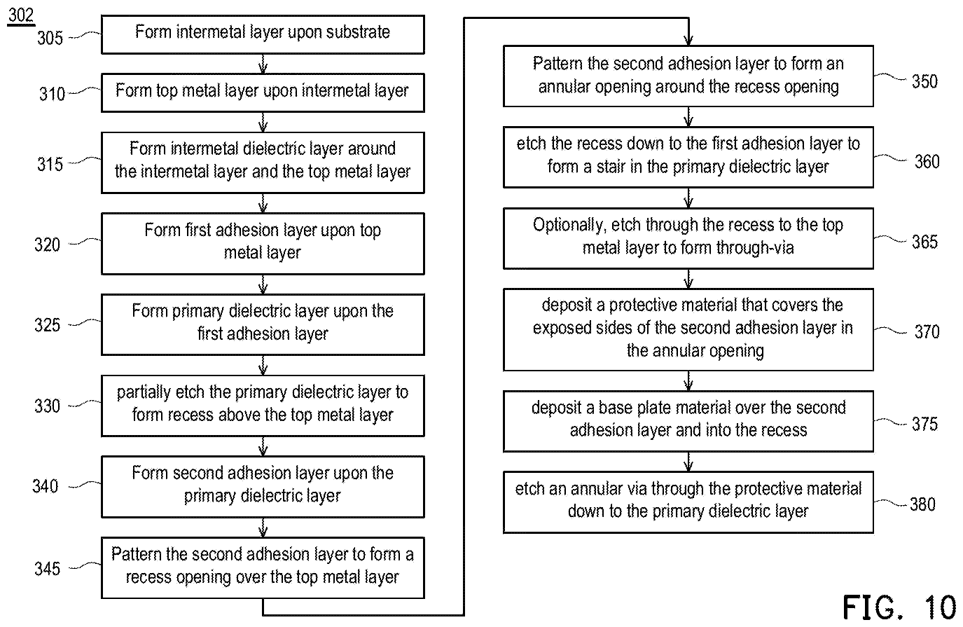

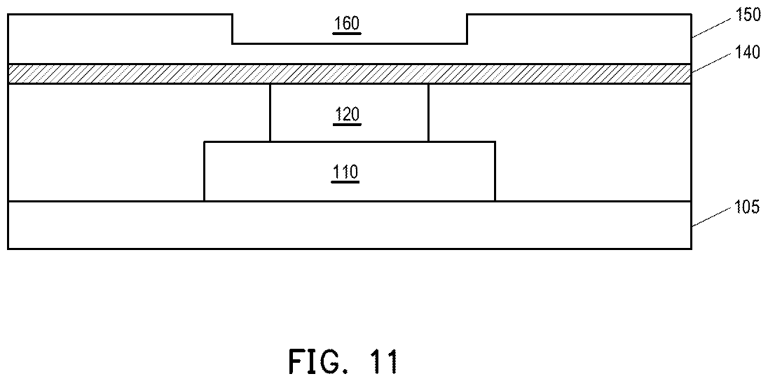

FIG. 10 is a flow chart illustrating a second method 302 for forming a base plate for a MEMS device 104, and for forming one or more chemical stop structures to reduce etching of an adhesion layer, in accordance with some embodiments. Some steps of the method are also illustrated in FIGS. 11-13.

The second method of FIG. 10 differs from the first method of FIG. 2 in that in step 330, the primary dielectric layer 150 is partially etched before the second adhesion layer 180 is formed. FIG. 11 shows the structure after the primary dielectric layer 150 is partially etched to form the recess 160.

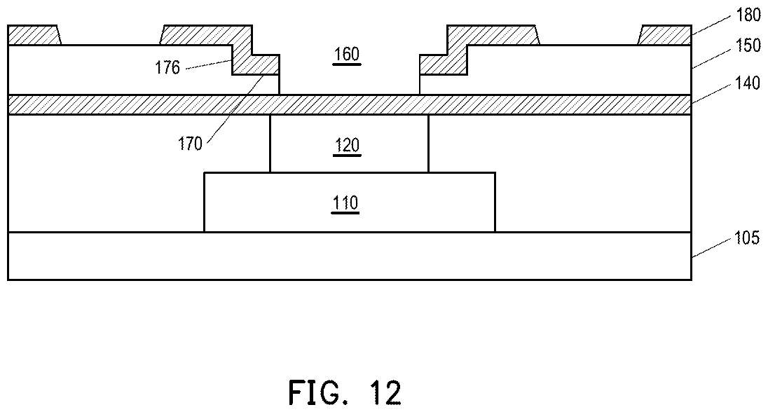

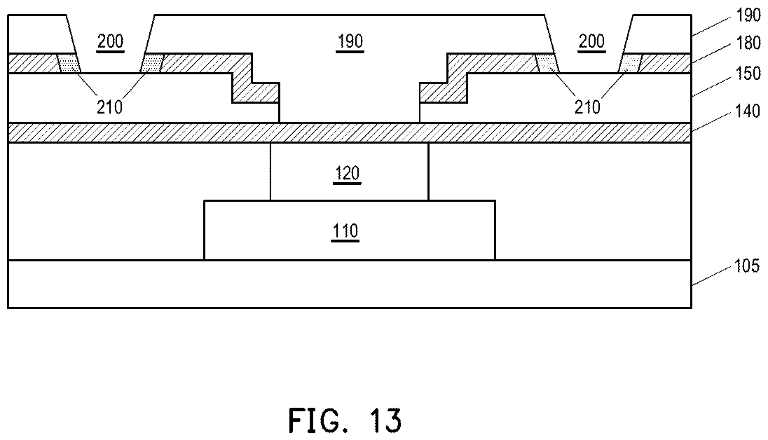

Then in step 340, the second adhesion layer 180 is formed upon the primary dielectric layer. It is noted that the second adhesion layer is formed as a conformal film upon the primary dielectric layer. FIG. 12 shows the structure after steps 345-350. As seen here, in this embodiment the second adhesion layer 180 is present upon the surfaces of the upper rise 176 and the stair 170, but still does not contact the first adhesion layer 140. The annular opening 184 in the second adhesion layer 180 is also visible. FIG. 13 shows the structure after steps 360-380 are performed to deposit the protective material 210, form the base plate layer 190, and form the annular via 200.

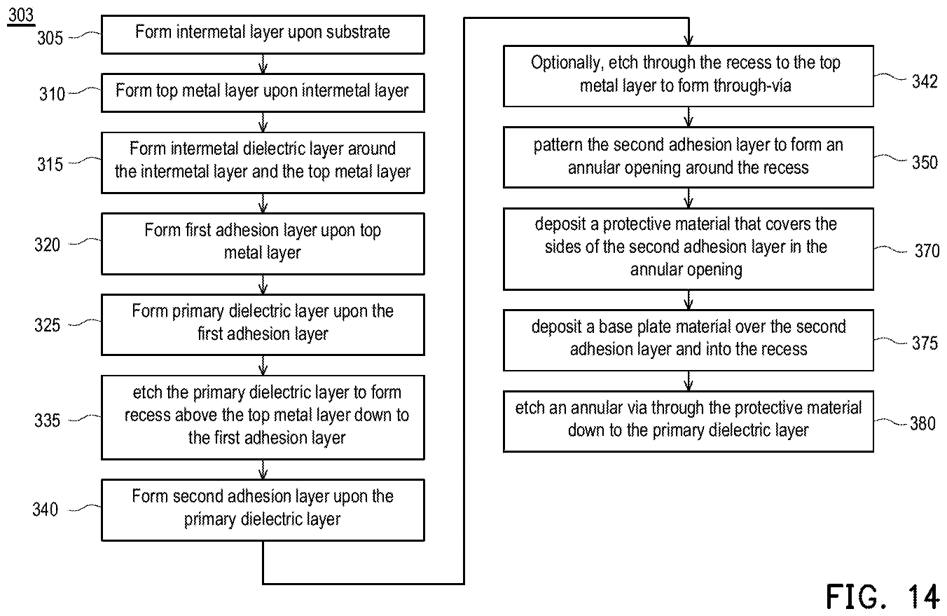

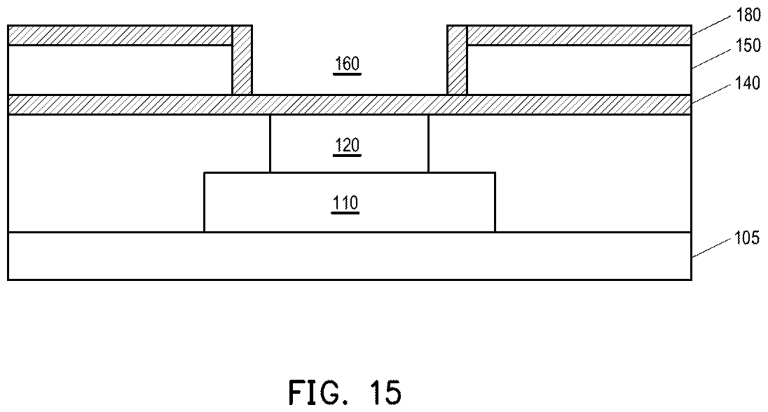

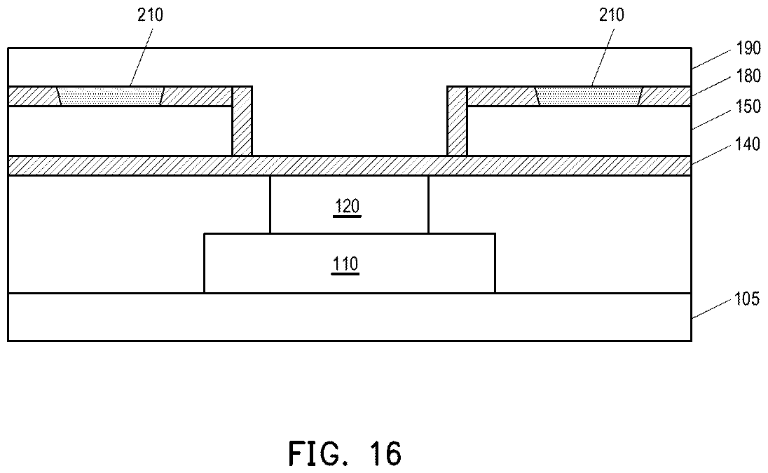

FIG. 14 is a flow chart illustrating a third method 303 for forming a base plate for a MEMS device 102, and for forming one or more chemical stop structures to reduce etching of an adhesion layer, in accordance with some embodiments. Some steps of the method are also illustrated in FIG. 15 and FIG. 16.

The third method of FIG. 14 differs from the first method of FIG. 2 in that in step 335, a recess 160 is formed in the primary dielectric layer 150 above the top metal layer 120, but the recess is etched down to the first adhesion layer 140. Then, the second adhesion layer 180 is deposited upon the primary dielectric layer 150. Optional step 342 in which etching is performed in the recess through the first adhesion layer 140 down to the top metal layer 120 to form the through-via, may be performed after either step 335 or 340. FIG. 15 shows the resulting structure. In this embodiment, then, the second adhesion layer 180 contacts the first adhesion layer 140. In addition, no stair 170 is present as in the first method of FIG. 2 (see also FIG. 1A) or the second method of FIG. 10 (see also FIG. 12). There is also no need to form a recess opening in the second adhesion layer, because the recess has already been formed. FIG. 16 shows the structure after steps 350-375 are performed to deposit the protective material 210 and form the base plate layer 190. FIG. 1E shows the structure after the annular via 200 is formed in step 380.

The devices and methods of the present disclosure include several different dielectric structures. Such dielectric structures can generally be made from any suitable combination of dielectric materials, although the characteristics of any particular layer may also be further defined. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

It is also noted that certain conventional steps are not expressly described in the discussion above. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarization of a surface may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

The MEMS devices including the MEMS structures of the present disclosure include chemical stop structures that reduce or prevent attack of the adhesion layers by etching chemicals such as hydrogen peroxide or potassium hydroxide. This reduces peeling of the base plate and improves the robustness of the MEMS structure. The MEMS devices might be used in various applications such as ion-beam lithography or charging-beam lithography.

Some embodiments of the present disclosure thus relate to methods for forming a base plate for a MEMS device. A first adhesion layer is formed upon a top metal layer. A primary dielectric layer is formed upon the first adhesion layer. A second adhesion layer is formed upon the primary dielectric layer. The second adhesion layer is patterned to form a recess opening and an annular opening around the recess opening. The primary dielectric layer is partially etched to form a recess above the top metal layer. A protective material is then deposited that covers the sides of the second adhesion layer in the annular opening. In some embodiments, the recess is also etched down to the first adhesion layer to form a stair in the primary dielectric layer. If desired, further etching within the recess can be performed to form a through-via to the top metal layer. A base plate material is then deposited over the second adhesion layer (and into the recess, if present). An annular via is then etched through the protective material (and the base plate material) down to the primary dielectric layer. The protective material separates the annular via from the second adhesion layer.

Also disclosed in various embodiments are MEMS structures that comprise a top metal layer and a first adhesion layer over the top metal layer. A primary dielectric layer is present upon the first adhesion layer. The primary dielectric layer includes a recess with a stair. A second adhesion layer is present upon the primary dielectric layer. The second adhesion layer includes a recess opening above the recess and an annular opening. A protective material covers the sides of the second adhesion layer in the annular opening. A base plate layer covers the second adhesion layer and fills the recess. An annular via passes through the base plate layer and the protective material down to the primary dielectric layer. The protective material separates the annular via from the second adhesion layer.

Further disclosed in various embodiments are MEMS structures that comprise a top metal layer and a first adhesion layer over the top metal layer. A primary dielectric layer is present upon the first adhesion layer. A second adhesion layer is present upon the primary dielectric layer. The second adhesion layer includes an annular opening. A protective material covers the sides of the second adhesion layer in the annular opening. A base plate layer covers the second adhesion layer. An annular via passes through the base plate layer and the protective material down to the primary dielectric layer. The protective material separates the annular via from the second adhesion layer.

Continuing, also disclosed in various embodiments are MEMS structures that comprise a top metal layer and a first adhesion layer over the top metal layer. A primary dielectric layer is present upon the first adhesion layer. The primary dielectric layer includes a recess with a stair. A second adhesion layer is present upon the primary dielectric layer. The second adhesion layer includes a recess opening above the recess and an annular opening. A base plate layer covers the second adhesion layer and fills the recess. An annular via passes through the base plate layer to the primary dielectric layer.

Also disclosed in various embodiments are other methods for forming a chemical stop structure between a first adhesion layer and a second adhesion layer. A first adhesion layer is formed upon a top metal layer. A primary dielectric layer is formed upon the first adhesion layer. A second adhesion layer is formed upon the primary dielectric layer. A recess opening is formed in the second adhesion layer. The primary dielectric layer is partially etched to form a recess. The recess is then further etched down to the first adhesion layer to form a stair in the primary dielectric layer. A base plate material is deposited into the recess. The base plate material is different from the second adhesion layer and forms the chemical stop structure.

Also disclosed in various embodiments are additional methods for forming a chemical stop structure in a MEMS structure. A primary dielectric layer is formed upon a first adhesion layer. A recess is formed in the primary dielectric layer. A second adhesion layer is then formed upon the primary dielectric layer. An annular opening is formed in the second adhesion layer around the recess. A protective material is deposited that covers the sides of the second adhesion layer in the annular opening. A base plate material is deposited over the second adhesion layer and into the recess. An annular via is etched through the protective material down to the primary dielectric layer. The protective material forms the chemical stop structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a base plate for a MEMS device, comprising:
forming a first adhesion layer upon a top metal layer;
forming a primary dielectric layer upon the first adhesion layer;
forming a second adhesion layer upon the primary dielectric layer;
patterning the second adhesion layer to form a recess opening above the top metal layer and an annular opening around the recess opening;
partially etching the primary dielectric layer to form a recess through the recess opening above the top metal layer;
depositing a protective material that covers the sides of the second adhesion layer in the annular opening;
depositing a base plate material over the second adhesion layer and into the recess; and
etching an annular via through the protective material down to the primary dielectric layer, wherein the protective material separates the annular via from the second adhesion layer.

2. The method of claim 1, further comprising, prior to depositing the base plate material:
etching the recess down to the first adhesion layer to form a stair in the primary dielectric layer.

3. The method of claim 1, further comprising, prior to forming the first adhesion layer:
forming an intermetal layer upon a substrate;
forming the top metal layer upon the intermetal layer;
forming an intermetal dielectric layer around the intermetal layer and the top metal layer.

4. The method of claim 1, wherein the first adhesion layer and the second adhesion layer are made of titanium.

5. The method of claim 4, wherein the protective material is a metal that is different from the second adhesion layer.

6. The method of claim 1, wherein the protective material is copper or nickel.

7. The method of claim 1, wherein the base plate material is a metal.

8. The method of claim 1, wherein the protective material and the base plate material are the same material.

9. The method of claim 1, wherein the annular via has a taper angle of about 30° to about 135° C.

10. The method of claim 1, wherein the protective material has a width of up to about 10 micrometers.

11. The method of claim 1, wherein the stair has a width of up to about 100 micrometers.

12. The method of claim 1, wherein the annular via has a minimum width of about 0.1 micrometers to about 100 micrometers.

13. The method of claim 1, wherein the top metal layer is formed from copper.

14. The method of claim 1, wherein the second adhesion layer is present upon the stair in the primary dielectric layer.

15. A structure, comprising:
a top metal layer;
a first adhesion layer over the top metal layer;
a primary dielectric layer upon the first adhesion layer, the primary dielectric layer including a recess;
a second adhesion layer upon the primary dielectric layer that includes a recess opening above the recess and an annular opening;
a protective material that covers the sides of the second adhesion layer in the annular opening;
a base plate layer that covers the second adhesion layer and fills the recess; and
an annular via through the base plate layer down to the primary dielectric layer.

16. The structure of claim 15, wherein the recess of the primary dielectric layer includes a stair.

17. The structure of claim 15, further comprising a through-via from the recess through the first adhesion layer to the top metal layer.

18. The structure of claim 15, wherein the protective material separates the annular via from the second adhesion layer.

19. A method for forming a chemical stop structure between a first adhesion layer and a second adhesion layer, comprising:
forming a primary dielectric layer upon the first adhesion layer;
forming a second adhesion layer upon the primary dielectric layer;
forming a recess opening in the second adhesion layer;
partially etching the primary dielectric layer to form a recess;
etching the recess down to the first adhesion layer to form a stair in the primary dielectric layer; and
depositing a base plate material into the recess, wherein the base plate material is different from the second adhesion layer and forms the chemical stop structure.

20. The method of claim 19, further comprising:
forming an annular opening around the recess opening in the second adhesion layer;
depositing a protective material that covers the sides of the second adhesion layer in the annular opening; and
etching an annular via through the protective material down to the primary dielectric layer, wherein the protective material separates the annular via from the second adhesion layer.
